(19) United States
(12) Patent Application Publication
(10) Pub. No.: US 2025/0191540 A1
(43) Pub. Date: Jun. 12, 2025

(54) GATE DRIVING CIRCUIT AND DISPLAY DEVICE INCLUDING THE SAME

(71) Applicant: LG Display Co., Ltd., Seoul (KR)

(72) Inventors: Hyun Woo JANG, Paju-si (KR); Beom Jin KIM, Paju-si (KR)

(21) Appl. No.: 18/752,555

(22) Filed: Jun. 24, 2024

(30) Foreign Application Priority Data
Dec. 6, 2023 (KR) 10-2023-0175859

(51) Int. Cl. G09G 3/3266; G06F 3/01; G09G 3/20

(52) U.S. Cl. CPC G09G 3/3266; G06F 3/013; G09G 3/2092; G09G 2310/0286; G09G 2310/0297; G09G 2340/0407; G09G 2354/00

(57) ABSTRACT

A gate driving circuit according to an embodiment and a display device including the same are disclosed. The gate driving circuit includes a plurality of signal transmission parts connected in cascade by means of a line to which a start signal or a carry signal from a previous signaling unit is applied; a first switch part connected between an output end of each of the plurality of signal transmission parts and a gate line; and a second switch part connected between the gate line connected to the first switch part and a gate line connected to an output end of a next signal transmission part.

### CROSS-REFERENCE TO RELATED APPLICATION

This application claims priority to and the benefit of Korean Patent Application No. 10-2023-0175859, filed Dec. 6, 2023, the disclosure of which is incorporated herein by reference in its entirety.

### BACKGROUND

### Technical Field

The present disclosure relates to a gate driving circuit and a display device including the same.

### Description of the Related Art

Recently, there has been a growing interest in organic light-emitting display devices with high-resolution for augmented reality (AR) and virtual reality (VR) electronics. AR/VR electronic devices typically have high frame rates and short duty cycle ratios for vivid descriptions, it typically have high brightness operation characteristics in a short time.

AR/VR electronic devices use technology to make the resolution different depending on the focus position to which the user's gaze is directed. This technology works by driving the focal region on the screen, where the user's gaze is directed, at a higher resolution, while by driving the surrounding region of the focus region, at a lower resolution. This driving method may reduce the amount of transmission of image data or power consumption.

### BRIEF SUMMARY

The inventors recognize that in the driving of AR/VR devices, if the resolution is different in the x-axis direction and in the y-axis direction depending on the focus position, there is an advantage in the amount of data to be transmitted, but there is no advantage in the program time. If the resolution is varied only in the y-axis direction, the program time can be reduced by using the method of simultaneously applying gate signals, but the plurality of channels of a data driving circuit cannot be reduced.

The present disclosure is capable of solving, among others, all the above-described problems.

The present disclosure provides a gate driving circuit and a display device including the same.

It should be noted that technical features and characteristics of the present disclosure are not limited to those above-described, and other technical characteristics, features or improvements of the present disclosure will be apparent to those skilled in the art from the descriptions herein.

A gate driving circuit according to embodiments of the present disclosure may include a plurality of signal transmission parts connected in cascade by means of a line to which a start signal or a carry signal from a previous signaling unit is applied; a first switch part connected between an output end of each of the plurality of signal transmission parts and a gate line; and a second switch part connected between the gate line connected to the first switch part and a gate line connected to an output end of a next signal transmission part.

A display device according to embodiments of the present disclosure may include a pixel array in which data lines and gate lines intersect and a plurality of pixels is arranged in each of pixel lines; a data driving circuit configured to apply a data voltage through the data lines; and a gate driving circuit configured to apply a gate signal through the gate lines, wherein the gate driving circuit includes a plurality of signal transmission parts connected in cascade by means of a line to which a start signal or a carry signal from a previous signaling unit is applied; a first switch part connected between an output end of each of the plurality of signal transmission parts and a gate line; and a second switch part connected between the gate line connected to the first switch part and a gate line connected to an output end of a next signal transmission part.

According to the present disclosure, the data lines are disposed to be shared among adjacent pixels, and the switches for simultaneously driving a plurality of pixels in the x-axis direction and the switches for simultaneously driving the plurality of pixels in the y-axis direction are disposed on the gate lines, thereby implementing resolutions in different ways depending on the focus position and the type of images.

According to the present disclosure, the plurality of pixels may be simultaneously driven in the x-axis and y-axis directions, which may minimize the loss of the program time and reduce the plurality of channels of the data driving circuit.

According to the present disclosure, it is possible to adjust the resolutions in the x-axis and y-axis directions, thereby enabling low-power driving.

The effects of the present specification are not limited to the above-mentioned effects, and other effects that are not mentioned will be apparently understood by those skilled in the art from the following description and the appended claims.

### BRIEF DESCRIPTION OF THE SEVERAL VIEWS OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a block diagram illustrating a display device according to an embodiment of the present disclosure;

FIG. 2 is a diagram illustrating an example of a connection between pixels, data lines, and gate lines;

FIG. 3 is a diagram illustrating a gate driving circuit according to a first embodiment of the present disclosure;

FIGS. 4 to 12 are drawings to explain the operation of the gate driving circuit according to the first embodiment;

FIG. 13 is a diagram illustrating another example of a connection between pixels, data lines, and gate lines;

FIG. 14 is a diagram illustrating a gate driving circuit according to a second embodiment of the present disclosure;

FIGS. 15 to 22 are drawings to explain the operation of the gate driving circuit according to the second embodiment;

FIGS. 24 to 27 are drawings to explain the operation of a gate driving circuit according to a third embodiment; and

FIGS. 28 to 30 are drawings to explain the operation of a switch according to embodiments.

### DETAILED DESCRIPTION

Advantages and features of the present specification and methods of achieving them will become apparent with reference to example embodiments, which are described in detail, in conjunction with the accompanying drawings. However, the present specification is not limited to the embodiments to be described below and may be implemented in different forms, the embodiments are only provided to completely disclose the present disclosure and completely convey the scope of the present disclosure to those skilled in the art, and the claims are part of the disclosure.

Since the shapes, sizes, proportions, angles, numbers, and the like disclosed in the drawings for describing the embodiments of the present disclosure are only exemplary, the present disclosure is not limited to the illustrated items. The same reference numerals indicate the same components throughout the specification. Further, in describing the present disclosure, when it is determined that a detailed description of related known technology may unnecessarily obscure the gist of the present disclosure, the detailed description thereof will be omitted.

When ‘including,’ ‘having,’ ‘consisting,’ and the like mentioned in the present specification are used, other parts may be added unless ‘only’ is used. A case in which a component is expressed in a singular form includes a plural form unless explicitly stated otherwise.

In interpreting the components, it should be understood that an error range is included even when there is no separate explicit description.

In the case of a description of a positional relationship, for example, when the positional relationship of two parts is described as ‘on,’ ‘at an upper portion,’ ‘at a lower portion,’ ‘next to, and the like, one or more other parts may be located between the two parts unless ‘immediately’ or ‘directly’ is used.

Although first, second, and the like are used to describe various components, these components are not limited by these terms. These terms are only used to distinguish one component from another. Accordingly, a first component, which is mentioned, below may also be a second component within the technical spirit of the present disclosure.

The same reference numerals may refer to substantially the same elements throughout the present disclosure.

The following embodiments can be partially or entirely bonded to or combined with each other and can be linked and operated in technically various ways. The embodiments can be carried out independently of or in association with each other.

Hereinafter, various embodiments of the present disclosure will be described in detail with reference to the accompanying drawings.

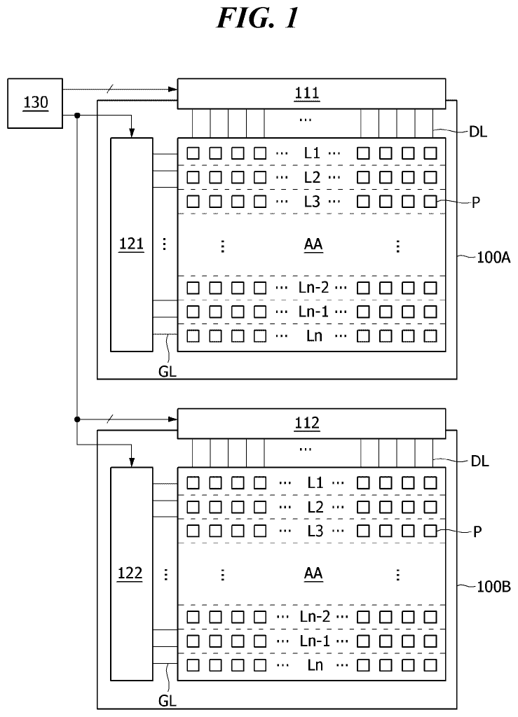

FIG. 1 is a block diagram illustrating a display device according to an embodiment of the present disclosure.

Referring to FIG. 1, the display device may include a first display panel 100A on which a left-eye image is displayed, and a second display panel 100B on which a right-eye image is displayed.

The display panels 100A and 100B include data lines DL, gate lines GL, and the pixels P. A screen of the display panels 100A and 100B includes a pixel array on which an image is displayed. The pixel array includes pixel lines L1 to Ln into which pixel data is written by being sequentially scanned by scan pulses shifted along a scanning direction.

The pixel array includes a plurality of pixel lines L1 to Ln. Each of the pixel lines L1 to Ln includes one line of pixels disposed in a line direction or a length direction (the X-axis direction) of display panel in the pixel array of the display panels 100A and 100B.

The display panel driver may include data driving circuits 111 and 112, gate driving circuits 121 and 122, a controller 130, and the like. The data driving circuits 111 and 112 and the gate driving circuits 121 and 122 may be separated for each of the display panels 100A and 100B, while the controller 130 may be shared.

The data driving circuits 111 and 112 convert the pixel data inputted from the controller 130 into voltage or current to supply data signals to the pixels.

A de-multiplexers DeMUX may further be disposed between the data driving circuits 111 and 112 and the data lines DL. The de-multiplexers DeMUX allow the data voltages output from the channels of the data driving circuit 111 and 112 to be sequentially supplied to the data lines DL. Each of the de-multiplexers may include a plurality of switch elements disposed on the display panel 100A and 100B. When the de-multiplexers are disposed between the output terminals of the data driving circuits 111 and 112 and the data lines DL, the plurality of channels of the data driving circuits 111 and 112 may be reduced. The de-multiplexers DeMUX may be omitted.

The gate driving circuits 121 and 122 may sequentially output scan pulses synchronized with the data signals outputted from the data driving circuits 111 and 112 under the control of the controller 130.

The gate driving circuits 121 and 122 may sequentially supply the gate signals to the gate lines 103 by shifting the gate signals using a shift register.

The controller 130 receives digital video data of an input image and timing signals synchronized with the digital video data from the host system (not shown). The timing signals may include a vertical synchronization signal Vsync, a horizontal synchronization signal Hsync, a main clock CLK, a data enable signal DE, and the like. The vertical synchronization signal Vsync and the horizontal synchronization signal Hsync may be omitted since a vertical period and a horizontal period may be obtained by a method of counting the data enable signal DE. The data enable signal DE has a period of one horizontal period 1H.

Based on the timing signals Vsync, Hsync, and DE received from the host system, the controller 130 generates a data timing control signal for controlling the operation timing of the data driving circuit, and a gate timing control signal for controlling the operation timing of the gate driving circuit.

The voltage level of the gate timing control signal output from the controller 130 may be converted to a gate-on voltages VGH and VEH and a gate-off voltages VGL and VEL by means of a level shifter (not shown) and then supplied to the gate driving circuit. That is, the level shifter converts a low level voltage of the gate timing control signal into the gate-off voltages VGL and VEL and converts a high level voltage of the gate timing control signal into the gate-on voltages VGH and VEH. The gate timing signal includes the start pulse and the shift clock.

The controller 130 may receive information about the user's focus position from an external system, divide the screen into a plurality of areas according to the received focus position, generate a gate timing control signal for each area to be applied, and then provides it to the gate driving circuit.

In this case, the controller 130 may set an area having a predetermined size including a focus position to which the user's gaze is directed as a high-resolution area, and discriminate the remaining area as a low-resolution area.

The controller 130 may also analyze image data input from the external system, divide the screen into a plurality of areas according to the result of the analysis, generate a gate timing control signal for each area to be applied, and provide it to the gate driving circuit.

In this case, the controller 130 may categorize the image data into a type of images containing a lot of x-axis direction's high-frequency components and a type of images containing a lot of y-axis direction's high-frequency components.

Further, the controller 130 may divide the screen into a plurality of areas based on the focus position and the type of images when the focus position is provided by the external system, and may divide the screen into a plurality of areas based on the type of images when the focus position is not provided.

For example, the data driving circuits 111 and 112, the gate driving circuit 121 and 122, the controller 130, and the like may be integrated into one drive IC (DIC) in mobile devices or wearable devices.

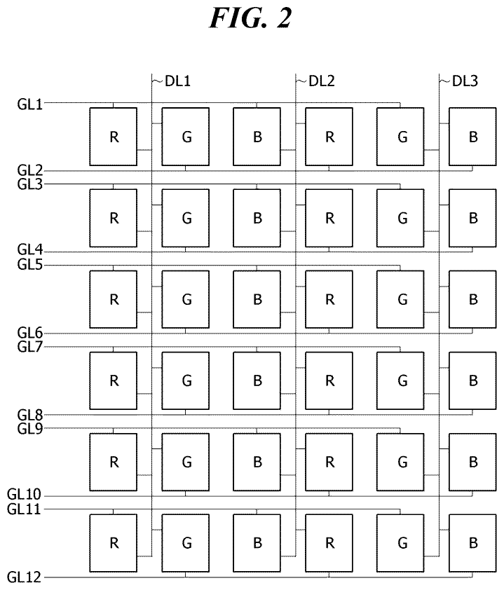

FIG. 2 is a diagram illustrating an example of a connection between pixels, data lines, and gate lines.

Referring to FIG. 2, each of the pixels P may be divided into a red pixel (or subpixel), a green pixel (or subpixel), and a blue pixel (or subpixel) for color implementation. Each of the pixels P may further include a white pixel. Each of the pixels P includes a pixel circuit. The pixel circuit is connected to the data lines DL and the gate lines GL.

The pixels P may include a first pixel (or red pixel), a second pixel (or green pixel), and a third pixel (or blue pixel) of different colors that are sequentially arranged for each pixel line.

A data line DL may be disposed between two adjacent pixels and shared by two adjacent pixels.

A gate lines GL may be disposed in a unit of a pixel line and connected to the pixels in that pixel line. An odd-numbered gate line may be connected to odd-numbered pixels in the pixel line, and an even-numbered gate line may be connected to even-numbered pixels in the pixel line.

The arrangements of the pixels P, the data lines DL, and the gate lines GL described herein is merely an example, and may be designed in a variety of arrangements without being limited thereto.

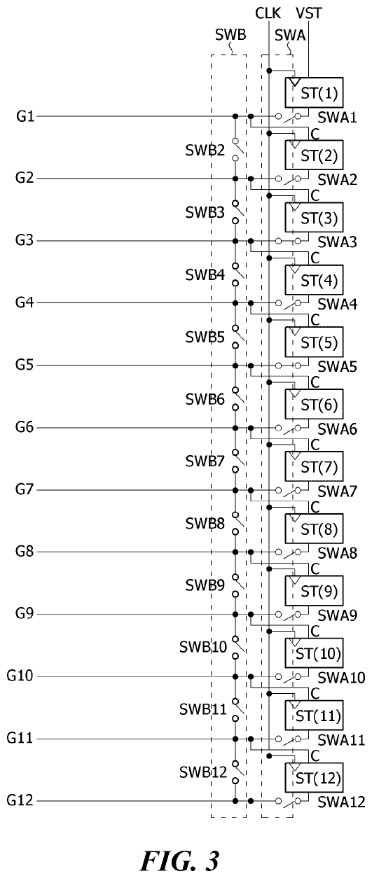

FIG. 3 is a diagram illustrating a gate driving circuit according to a first embodiment of the present disclosure.

Referring to FIG. 3, a gate driving circuit according to a first embodiment of the present disclosure may include a plurality of signal transmission parts ST, e.g., ST(1) to ST(12), connected in cascade, a first switch part SWA, and a second switch part SWB. A configuration including 12 signal transmission parts, a first signal transmission part ST(1) to a twelfth signal transmission part ST(12), is described herein as an example, but the disclosure is not limited thereto.

Each of the signal transmission parts ST(1) to ST(12) receives a start pulse VST or a carry signal C output from a previous signal transmission part and a clock signal CLK. The first signal transmission part ST(1) starts to drive according to the start pulse VST, and the remaining signal transmission parts ST(2) to ST(12) start to drive by receiving the carry signal C from their previous signal transmission parts.

The respective signal transmission parts ST(1) to ST(12) sequentially output the gate signals G1 to G12 by shifting the start pulse VST or the carry signal C output from the previous signal transmission parts according to the timing of the clock signal CLK.

The first switch part SWA (shown as including switches SWA1-SWA12) may be connected to the output ends of the respective signal transmission parts ST(shown as ST(1) to ST(12)). The first switch part SWA may pass or block the gate signals output from the respective signal transmission parts ST(1) to ST(12). For example, when a switch of the first switch part SWA, e.g., SWA1, is turned on, the gate signal output from the respective signal transmission part ST, e.g., ST(1), may be supplied to the respective gate line, e.g., G1. When a switch of the first switch part SWA, e.g., SWA1, is turned off, the gate signal output from the respective signal transmission part ST, e.g., ST(1), may be blocked from being supplied to the respective gate line, e.g., G1.

For example, the first switch part SWA has one end connected to the output end of the respective signal transmission part, and the other end connected to the respective gate line.

The second switch part SWB (shown as including switches SWB1-SWB12) may establish a connection for simultaneous driving between the pixels of the same color in the first-axis direction, i.e., in the x-axis direction. The second switch part SWB may be connected between the gate lines connected to the respective output ends of two adjacent signal transmission parts. The second switch part SWB may supply the gate signals output from the signal transmission parts to the gate lines connected to the output ends of the adjacent signal transmission parts. The second switch part SWB may simultaneously supply a gate signal output from at least one signal transmission part to a gate line connected to an output end of at least one another signal transmission part.

For example, the second switch part SWB has one end connected to an (n)th gate line, which is connected to the output end of an (n)th signal transmission part, and the other end connected to an (n+1)th gate line, which is connected to an output end of an (n+1)th signal transmission part.

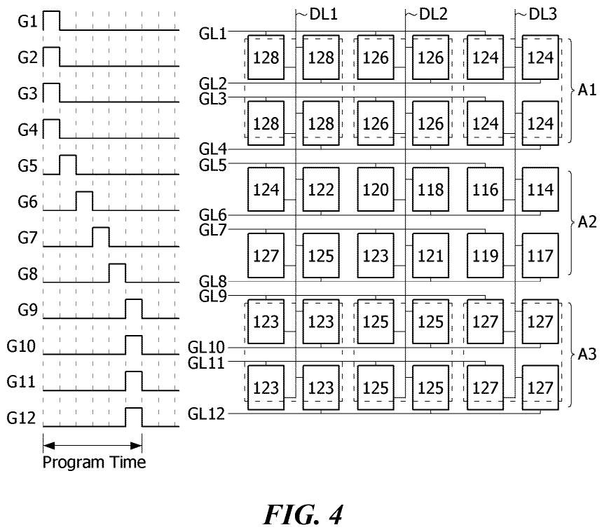

FIGS. 4 to 12 are drawings to explain the operation of the gate driving circuit according to the first embodiment.

Referring to FIG. 4, a screen may be divided into low-resolution areas A1 and A3, and a high-resolution area A2 depending on the focus position. In the low-resolution region A1, a plurality of pixels may be driven simultaneously in the x-axis and y-axis directions; in the high-resolution area A2, a plurality of pixels may be driven individually; and in the low-resolution region A3, a plurality of pixels may be driven simultaneously in the x-axis and y-axis directions.

For example, gate signals G1 to G4 are simultaneously to applied to the low-resolution area A1 and gate signals G9 to G12 are simultaneously applied to the low-resolution areas A1 and A3, and gate signals G5 to G8 sequentially and individually to the high-resolution area A2.

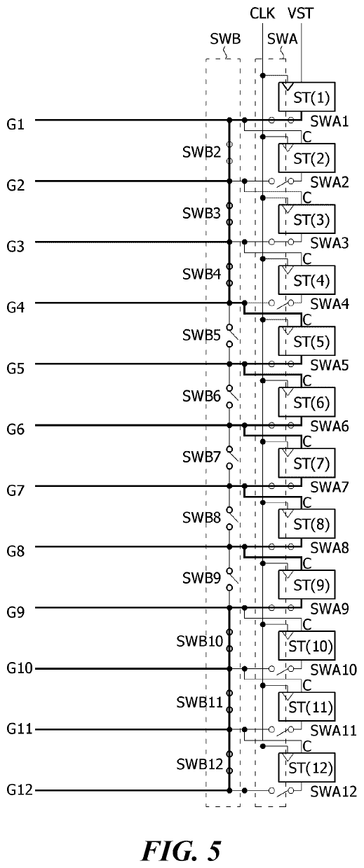

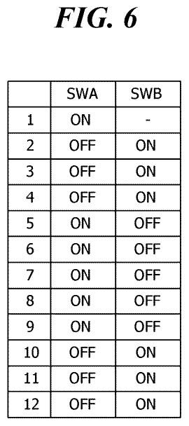

Referring to FIGS. 5 and 6, in the gate driving circuit according to an embodiment, in the low-resolution area A1, a first signal transmission unit ST(1) receiving the start signal VST is driven, and a first switch SWA1 in the first switch SWA and second switches SWB2, SWB3, and SWB4 in the second switch SWB are turned on, so that the gate lines are connected to the first signal transmission unit ST1 to simultaneously supply first, second, third, and fourth gate signals G1, G2, G3, and G4 to the gate lines.

In the gate driving circuit, in the high-resolution area A2, fifth, sixth, seventh, and eighth signal transmission parts ST(5), ST(6), ST(7), and ST(8), which receive the signal output from the first switch SWA1 in the first switch part SWA as a carry signal, are sequentially driven, and respective switches SWA5, SWA6, SWA7, and SWA8 in the first switch part SWA are turned on, so that fifth, sixth, seventh, and eighth gate signals G5, G6, G7, and G8 are sequentially supplied to the respective gate lines.

In the gate driving circuit, in the low-resolution area A3, ninth signal transmission part ST(9), which receives the signal output from the eighth switch SWA8 in the first switch part SWA as a carry signal, is driven, and a ninth switch SWA9 in the first switch part SWA and tenth to twelfth switches SWB10 to SWB12 in the second switch part SWB are turned on, so that the gate twelfth gate signals G9 to G12 to the respective gate lines.

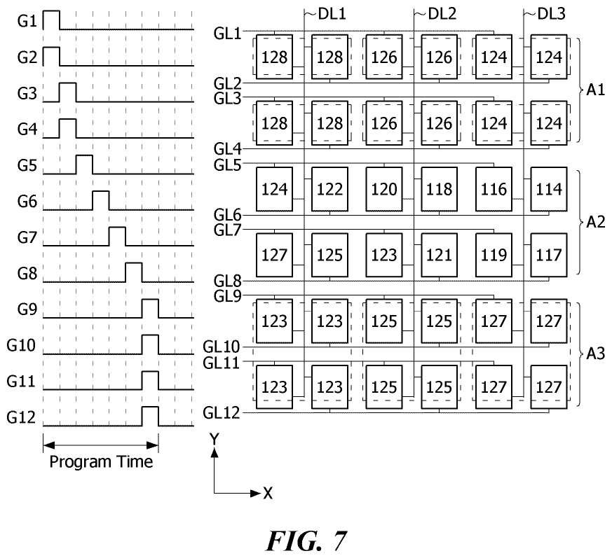

Referring to FIG. 7, a screen may be divided into low-resolution areas A1 and A3, and a high-resolution area A2 depending on the focus position and the type of an image. In the low-resolution area A1, a plurality of pixels may be driven simultaneously in the x-axis direction; in the high-resolution area A2, a plurality of pixels may be driven individually; and in the low-resolution area A3, a plurality of pixels may be driven simultaneously in the x-axis and y-axis directions.

The reason for simultaneously driving the plurality of pixels in the low-resolution region A1 in the x-axis direction is that the image data containing a lot of the x-axis direction's high-frequency components is input.

For this purpose, the gate signals G1 and G2 (of a same pixel line along the x-axis) are applied simultaneously and G3 and G4 (of a same pixel line along the x-axis) are applied simultaneously, which could be different in timing from that of gate signals G1 and G2, to the low-resolution area A1; the gate signals G5 to G8 are applied sequentially and individually to the high-resolution area A2; and the gate signals G9 to G12 simultaneously to the low-resolution area A3.

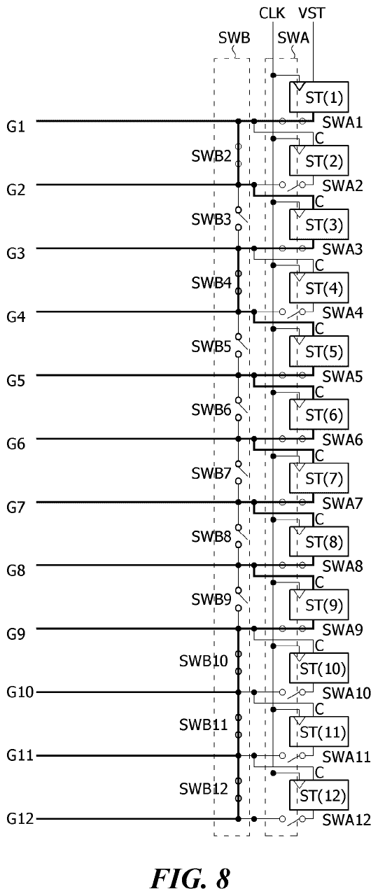

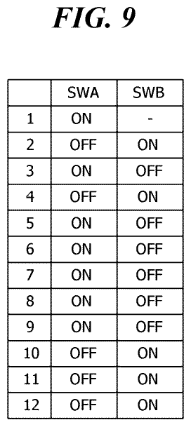

Referring to FIGS. 8 to 9, in the gate driving circuit according to an embodiment, in the low-resolution area A1, a first signal transmission part ST(1) receiving a start signal VST is driven, and a first switch SWA1 in the first switch part SWA and a second switch SWB2 in the second switch part SWB are turned on, so that first to second gate signals G1 to G2 are simultaneously supplied to the gate lines, while a third switch SWA3 in the first switch part SWA and a fourth switch SWB4 in the second switch part SWB are turned on, so that third to fourth gate signals G3 to G4 are simultaneously supplied to the gate lines.

In the gate driving circuit, in the high-resolution area A2, fifth to eighth signal transmission parts ST(5) to ST(8), which receive the signal output from the third switch SWA3 in the first switch part SWA as a carry signal, are sequentially driven, and fifth to eighth switches SWA5 to SWA8 in the first switch part SWA are turned on, so that fifth to eighth gate signals G5 to G8 are sequentially supplied to the gate lines.

In the gate driving circuit, in the low-resolution area A3, ninth signal transmission part ST(9), which receives the signal output from the eighth switch SWA8 in the first switch part SWA as a carry signal, is driven, and a ninth switch SWA9 in the first switch part SWA and tenth to twelfth switches SWB10 to SWB12 in the second switch part SWB are turned on, so that the gate twelfth gate signals G9 to G12 to the gate lines.

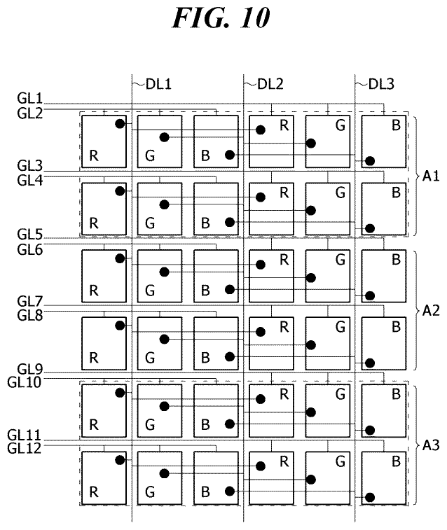

With reference to FIG. 10, there is shown a case in which the connection structure of the data lines is modified, wherein pixels of the same color in the same pixel line are connected to the same data line. In this structure, a screen may be divided into low-resolution areas A1 and A3 and a high-resolution area A2 depending on the focus position In the low-resolution area A1, a plurality of pixels may be driven simultaneously in the x-axis direction; in the high-resolution area A2, a plurality of pixels may be driven individually; and in the low-resolution area A3, a plurality of pixels may be driven simultaneously in the x-axis and y-axis directions.

In the low-resolution area A1, the pixels of the same color in the x-axis direction are connected to the same data line, and therefore the pixels of the same color in the x-axis direction may be driven simultaneously.

For example, gate signals G1 to G4 are simultaneously applied to the low-resolution areas A1, gate signals G9 to G12 are simultaneously applied to the low-resolution areas A3, and gate signals G5 to G8 are sequentially and individually applied to the high-resolution area A2.

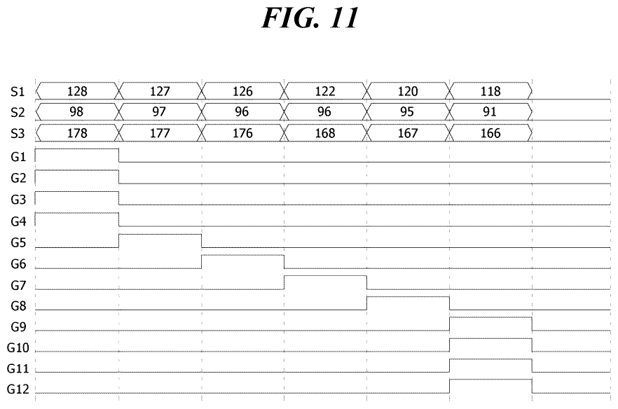

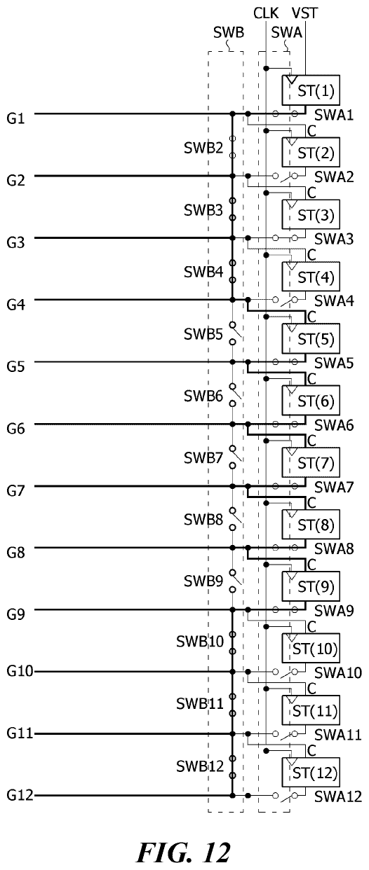

Referring to FIGS. 11 and 12, in the gate driving circuit according to an embodiment, in the low-resolution area A1, a first signal transmission unit ST(1) receiving the start signal VST is driven, and a first switch SWA1 in the first switch SWA and second to fourth switches SWB2 to SWB4 in the second switch SWB are turned on, so that the gate lines are connected to the first signal transmission unit ST1 to simultaneously supply first to fourth gate signals G1 to G4 to the respective gate lines.

In the gate driving circuit, in the high-resolution area A2, fifth to eighth signal transmission parts ST(5) to ST(8), which receive the signal output from the first switch SWA1 in the first switch part SWA as a carry signal, are sequentially driven, and fifth to eighth switches SWA5 to SWA8 in the first switch part SWA are turned on, so that fifth to eighth gate signals G5 to G8 to be sequentially supplied to the respective gate lines.

In the gate driving circuit, in the low-resolution area A3, ninth signal transmission part ST(9), which receives the signal output from the eighth switch SWA8 in the first switch part SWA as a carry signal, is driven, and a ninth switch SWA9 in the first switch part SWA and tenth to twelfth switches SWB10 to SWB12 in the second switch part SWB are turned on, so that the gate twelfth gate signals G9 to G12 to the respective gate lines.

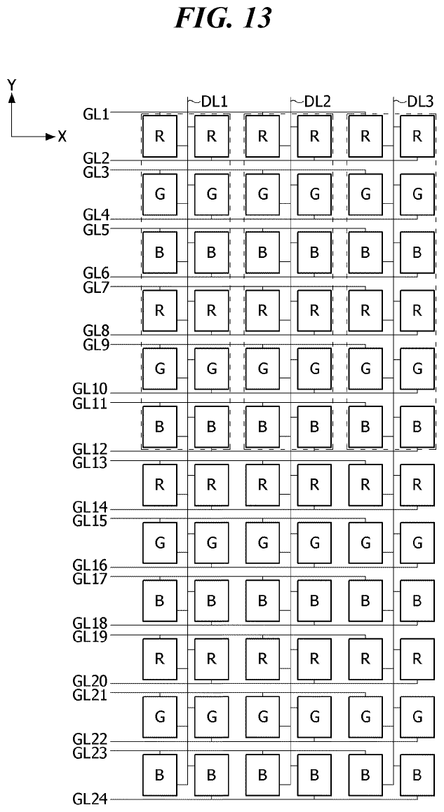

FIG. 13 is a diagram illustrating another example of a connection between pixels, data lines, and gate lines.

Referring to FIG. 13, each of the pixels P may be divided into a red pixel (or subpixel), a green pixel (or subpixel), and a blue pixel (or subpixel) for color implementation. Each of the pixels P may further include a white pixel. Each of the pixels P includes a pixel circuit. The pixel circuit is connected to the data lines DL and the gate lines GL.

The pixels P may include red pixels, green pixels, and blue pixels that are sequentially arranged for each pixel line, e.g., shown as in the x-axis. For example, red pixels R are arranged in a first pixel line, green pixels G are arranged in the second pixel line, and blue pixels B are arranged in the third pixel line.

A data line DL may be disposed between two adjacent pixels and shared by two adjacent pixels.

A gate lines GL may be disposed in a unit of a pixel line and connected to the pixels in that pixel line. An odd-numbered gate line may be connected to odd-numbered pixels in the pixel line, and an even-numbered gate line may be connected to even-numbered pixels in the pixel line.

The arrangements of the pixels P, the data lines DL, and the gate lines GL described herein is merely an example, and may be designed in a variety of arrangements without being limited thereto.

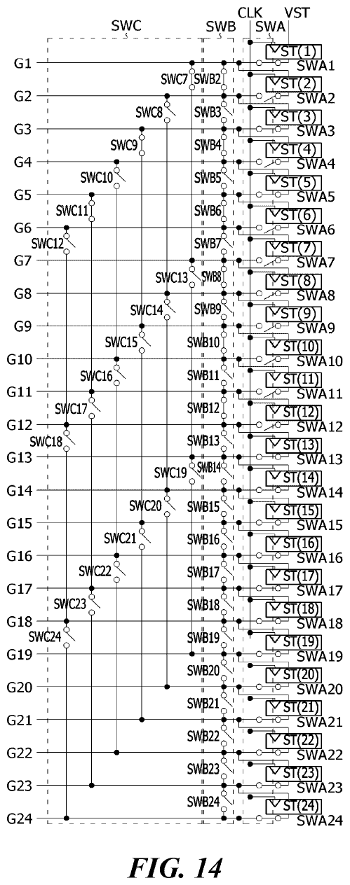

FIG. 14 is a diagram illustrating a gate driving circuit according to a second embodiment of the present disclosure.

Referring to FIG. 14, a gate driving circuit according to a second embodiment present disclosure may include a plurality of signal transmission parts ST, a first switch part SWA, a second switch part SWB, and a third switch part SWC.

Each of the signal transmission parts ST receives a start pulse VST or a carry signal and a clock signal CLK output from a previous signal transmission part. The first signal transmission part ST(1) starts to drive according to the start pulse VST, and the remaining signal transmission parts ST(2) to ST(12) start to drive by receiving the carry signal C from their previous signal transmission parts.

The respective signal transmission parts ST(1) to ST(12) sequentially output the gate signals G1 to G12 by shifting the start pulse VST or the carry signal C output from the previous signal transmission parts according to the timing of the clock signal CLK.

The first switch part SWA may be connected to the outputs of the respective signal transmission parts ST(1) to ST(12). The first switch part SWA may pass or block the gate signals output from the signal transmission parts ST(1) to ST(12). For example, when the first switch part SWA is turned on, the gate signals output from the signal transmission parts ST(1) to ST(12) may be supplied to the gate lines. When the first switch part SWA is turned off, the gate signals output from the signal transmission parts ST(1) to ST(12) may be blocked from being supplied to the gate lines.

For example, the first switch part SWA has one end connected to the output end of the signal transmission part, and the other end connected to the gate line.

The second switch part SWB may establish a connection for simultaneous driving between the pixels of the same color in the x-axis direction. The second switch part SWB may be connected between the gate lines connected to the respective output ends of two adjacent signal transmission parts. The second switch part SWB may supply the gate signals output from the signal transmission parts to the gate lines connected to the output ends of the adjacent signal transmission parts. The second switch part SWB may simultaneously supply a gate signal output from at least one signal transmission part to a gate line connected to an output end of the at least one signal transmission part.

For example, the second switch part SWB has one end connected to an (n)th gate line, which is connected to the output end of an (n)th signal transmission part, and the other end connected to an (n+1)th gate line, which is connected to an output end of an (n+1)th signal transmission part.

The third switch part SWC may establish a connection for simultaneous driving between the pixels of the same color in the second-axis direction perpendicular to the first-axis direction, i.e., in the y-axis direction. The third switch part SWC may be connected between the gate lines connected to different pixel lines in which the pixels of the same color are arranged. The third switch part SWC is connected at a position farther than the second switch part SWB on the gate lines connected to the output ends of the signal transmission parts, and may be connected in parallel with the second switch part SWB.

For example, the third switch part SWC has one end connected to an (n)th gate line, which is connected to the output end of an (n)th signal transmission part, and the other end connected to an (n+7)th gate line, which is connected to an output end of an (n+7)th signal transmission part.

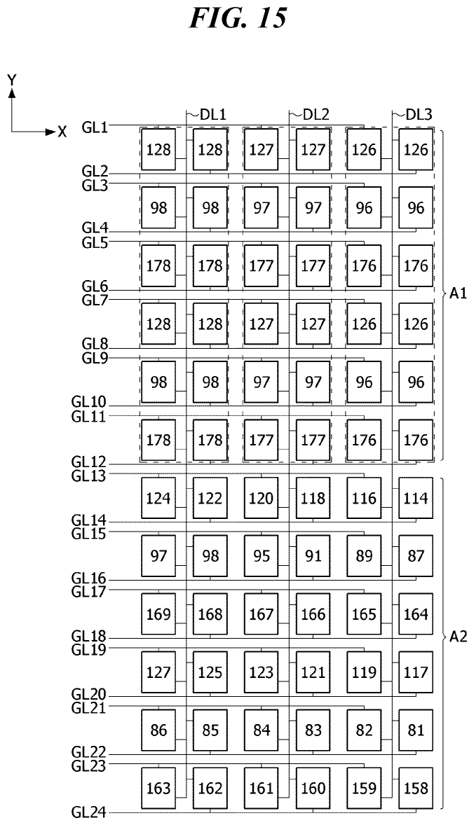

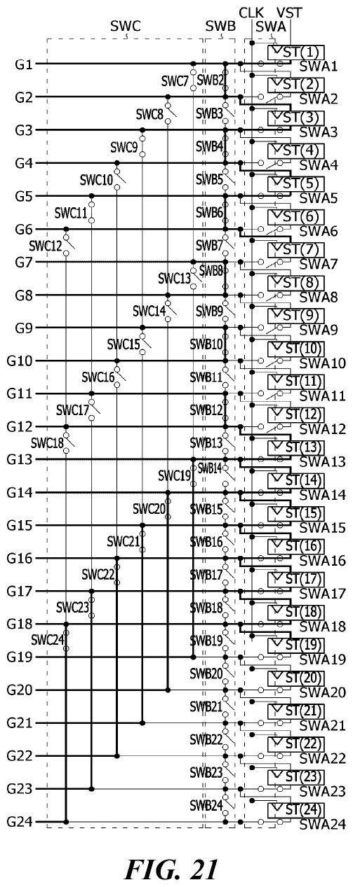

FIGS. 15 to 22 are drawings to explain the operation of the gate driving circuit according to the second embodiment.

Referring to FIG. 15, a screen may be divided into a low-resolution area A1 and a high-resolution area A2 depending on the focus position. In the low-resolution area A1, a plurality of pixels may be driven simultaneously by color in the x-axis and y-axis directions, while in the high resolution area A2, a plurality of pixels may be driven individually.

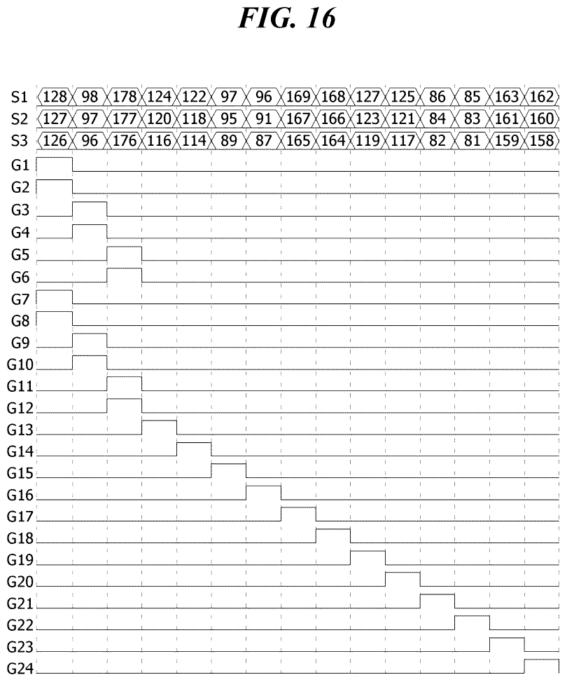

Referring to FIGS. 16 to 18, in the gate driving circuit according to an embodiment, in the low-resolution area A1, a first signal transmission part ST(1) receiving a start signal VST is driven, and a first switch SWA1 in the first switch part SWA and a second switch SWB2 in the second switch part SWB are turned on so that first to second gate signals G1 to G2 are simultaneously supplied to the gate lines, while a third switch SWC7 in the third switch part SWC and an eighth switch SWB8 in the second switch part SWB are turned on so that seventh to eighth gate signals G7 to G8 are simultaneously supplied to the gate lines.

Next, a third signal transmission part ST(3), which receives the signal output from the first switch SWA1 in the first switch part SWA as a carry signal, is driven, and a third switch SWA3 in the first switch part SWA and a fourth switch SWB4 in the second switch part SWB are turned on to simultaneously supply third to fourth gate signals G3 to G4 to the gate lines while a ninth switch SWC9 in the third switch part SWC and a tenth switch SWB10 in the second switch part SWB are turned on to simultaneously supply ninth to tenth gate signals G9 to G10 to the gate lines.

Next, a fifth signal transmission part ST(5), which receives the signal output from the fourth switch SWA4 in the first switch part SWA as a carry signal, is driven, and a fifth switch SWA5 in the first switch part SWA and a sixth switch SWB6 in the second switch part SWB are turned on to simultaneously supply fifth to sixth gate signals G5 to G6 to the gate lines, while an eleventh switch SWC11 in the third switch part SWC and a twelfth switch SWB12 in the second switch part SWB are turned on to simultaneously supply eleventh to twelfth gate signals G11 to G12 to the gate lines.

In the gate driving circuit, in the high-resolution area A2, a thirteenth signal transmission part ST(13), which receives the signal output from the twelfth switch SWA12 in the first switch part SWA as a carry signal, is driven, and thirteenth to twenty-fourth switches SWA13 to SWA24 in the first switch part SWA are turned on to sequentially supply thirteenth to twenty-fourth gate signals G13 to G24 to the gate lines.

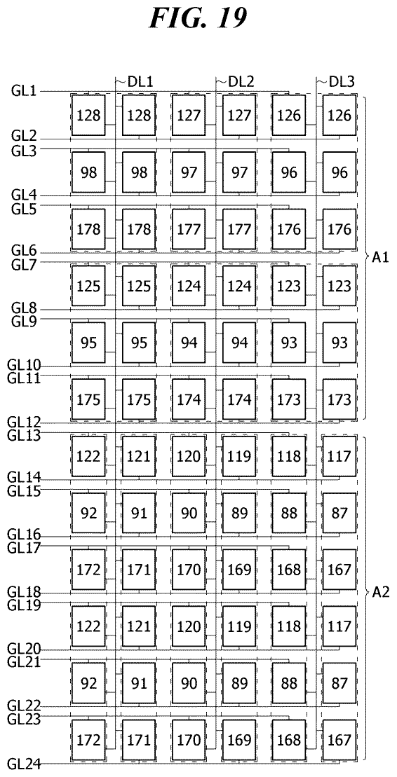

Referring to FIG. 19, a screen may be divided into a low-resolution areas A1 and a low-resolution area A2 depending on the focus position and the type of an image. In the low-resolution area A1, a plurality of pixels may be driven simultaneously by color in the x-axis direction, and in the low-resolution area A2, a plurality of pixels may be driven simultaneously by color in the y-axis direction.

The reason for simultaneously driving the plurality of pixels in the low-resolution region A1 in the x-axis direction is that the image data containing a lot of the x-axis direction's high-frequency components is input. Further, the reason for simultaneously driving the plurality of pixels in the y-axis direction in the low resolution region A1 is that the image data containing a lot of y-axis direction's high-frequency components is input.

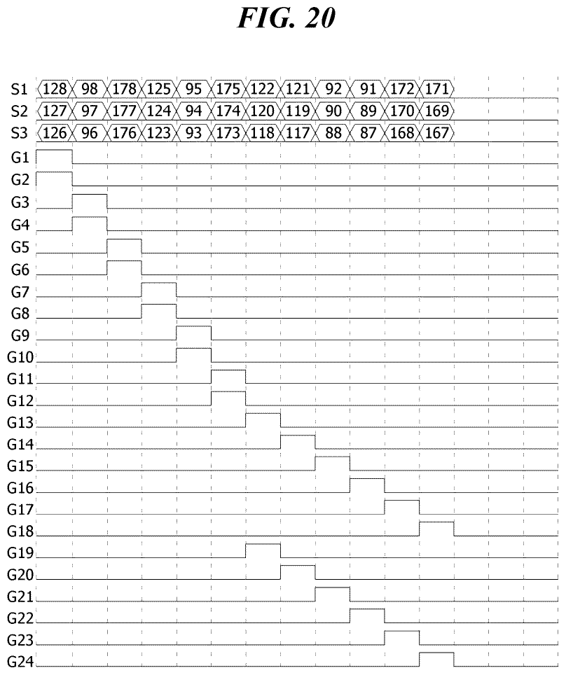

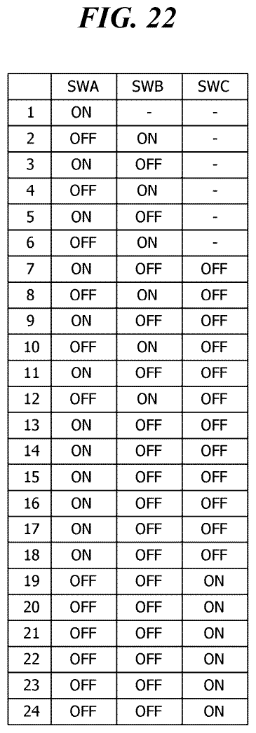

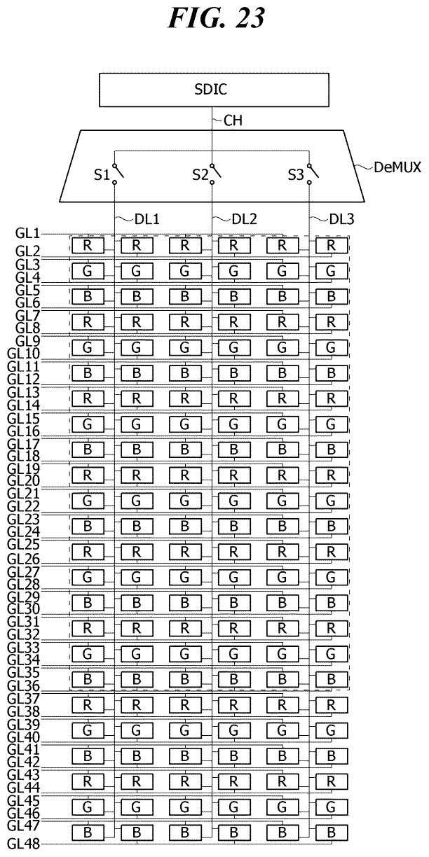

Referring to FIGS. 20 and 22, in the gate driving circuit according to an embodiment, in the low-resolution area A1, a first signal transmission unit ST(1) receiving the start signal VST is driven, and a first switch SWA1 in the first switch SWA and a second switch SWB2 in the second switch SWB are turned on so that the gate lines are connected to the first signal transmission unit ST1 to simultaneously supply first to second gate signals G1 to G2 to the gate lines.

Next, a third signal transmission part ST(3), which receives the signal output from the first switch SWA1 in the first switch part SWA as a carry signal, is driven, and a third switch SWA3 in the first switch part SWA and a fourth switch SWB4 in the second switch part SWB are turned on to simultaneously supply third to fourth gate signals G3 to G4 to the gate lines.

Next, a fifth signal transmission part ST(5), which receives the signal output from the third switch SWA3 in the first switch part SWA as a carry signal, is driven, and a fifth switch SWA5 in the first switch part SWA and a sixth switch SWB6 in the second switch part SWB are turned on to simultaneously supply fifth to sixth gate signals G5 to G6 to the gate lines.

Next, a seventh signal transmission part ST(7), which receives the signal output from the fifth switch SWA5 in the first switch part SWA as a carry signal, is driven, and a seventh switch SWA7 in the first switch part SWA and an eighth switch SWB8 in the second switch part SWB are turned on to simultaneously supply seventh to eighth gate signals G7 to G8 to the gate lines.

Next, a ninth signal transmission part ST(9), which receives the signal output from the seventh switch SWA7 in the first switch part SWA as a carry signal, is driven, and a ninth switch SWA9 in the first switch part SWA and a tenth switch SWB 10 in the second switch part SWB are turned on to simultaneously supply ninth to tenth gate signals G9 to G10 to the gate lines.

Next, an 11th signal transmission part ST(11), which receives the signal output from the ninth switch SWA9 in the first switch part SWA as a carry signal, is driven, and an 11th switch SWA11 in the first switch part SWA and a 12th switch SWB12 in the second switch part SWB are turned on to simultaneously supply 11th to 12th gate signals G11 to G12 to the gate lines.

In this way, the gate driving circuit may simultaneously drive a plurality of pixels per color.

In the gate driving circuit, in the low-resolution region A2, a 13th signal transmission part ST(13), which receives the signal output from the 11th switch SWA11 in the first switch part SWA as a carry signal, is driven, and a 13th switch SWA13 in the first switch part SWA and a 19th switch SWC19 in the third switch part SWC are turned on to simultaneously supply 13th and 19th gate signals G13 and G19 to the gate lines.

Next, a 14th signal transmission part ST(14), which receives the signal output from the 13th switch SWA13 in the first switch part SWA as a carry signal, is driven, and a 14th switch SWA14 in the first switch part SWA and a 20th switch SWC20 in the third switch part SWC are turned on to simultaneously supply 14th and 20th gate signals G14 and G20 to the gate lines.

Next, a 15th signal transmission part ST(15), which receives the signal output from the 14th switch SWA14 in the first switch part SWA as a carry signal, is driven, and a 15th switch SWA15 in the first switch part SWA and a 21st switch SWC21 in the third switch part SWC are turned on to simultaneously supply 15th and 21st gate signals G15 and G21 to the gate lines.

Next, a 16th signal transmission part ST(16), which receives the signal output from the 15th switch SWA15 in the first switch part SWA as a carry signal, is driven, and a 16th switch SWA16 in the first switch part SWA and a 22nd switch SWC22 in the third switch part SWC are turned on to simultaneously supply 16th and 22nd gate signals G16 and G22 to the gate lines.

Next, a 17th signal transmission part ST(17), which receives the signal output from the 16th switch SWA16 in the first switch part SWA as a carry signal, is driven, and a 17th switch SWA17 in the first switch part SWA and a 23rd switch SWC23 in the third switch part SWC are turned on to simultaneously supply 17th and 23rd gate signals G17 and G23 to the gate lines. Next, a 18th signal transmission part ST(18), which receives the signal output from the 17th switch SWA17 in the first switch part SWA as a carry signal, is driven, and an 18th switch SWA18 in the first switch part SWA and a 24th switch SWC24 in the third switch part SWC are turned on to simultaneously supply 18th and 24th gate signals G18 and G24 to the gate lines.

In this way, the gate driving circuit may reduce the program time while minimizing image quality loss by allowing the pixels in different pixel lines to be driven simultaneously per color.

Since the AR/VR electronic device has a small screen size, multiplexers may be used to reduce the signal lines between the data driving circuit and the panel due to limitations in the FPCB manufacturing and bonding process. Hereinafter, an operation principle of a device using a multiplexer will be described.

Referring to FIG. 23, each of the pixels P may be divided into a red pixel, a green pixel, and a blue pixel for color implementation. Each of the pixels may further include a white pixel. Each of the pixels P includes a pixel circuit. The pixel circuit is connected to the data lines DL and the gate lines GL.

The pixels P may include red pixels, green pixels, and blue pixels that are sequentially arranged for each pixel line.

A de-multiplexer (DeMUX) is disposed between the data driving circuit and the data lines DL, and the de-multiplexer may include a plurality of switch elements S1, S2, and S3. The plurality of switch elements S1, S2, and S3 may be driven by switching control signals S1_EN, S2_EN, and S3_EN. The switching control signals S1_EN, S2_EN, and S3_EN may be applied from the timing controller. A data line DL may be disposed between two adjacent pixels and shared by two adjacent pixels.

A gate lines GL may be disposed in a unit of a pixel line and connected to the pixels in that pixel line. An odd-numbered gate line may be connected to odd-numbered pixels in the pixel line, and an even-numbered gate line may be connected to even-numbered pixels in the pixel line.

The arrangements of the pixels P, the data lines DL, and the gate lines GL described herein is merely an example, and may be designed in a variety of arrangements without being limited thereto.

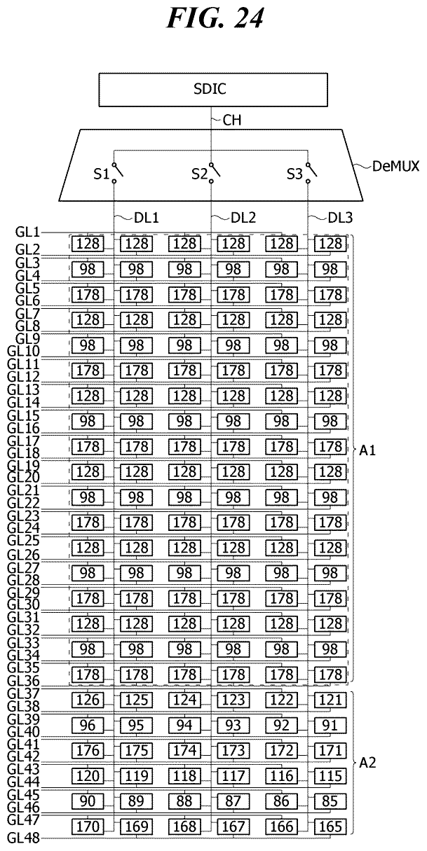

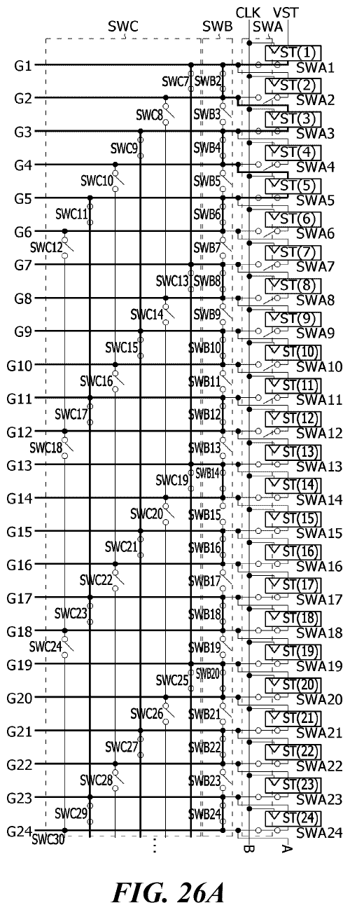

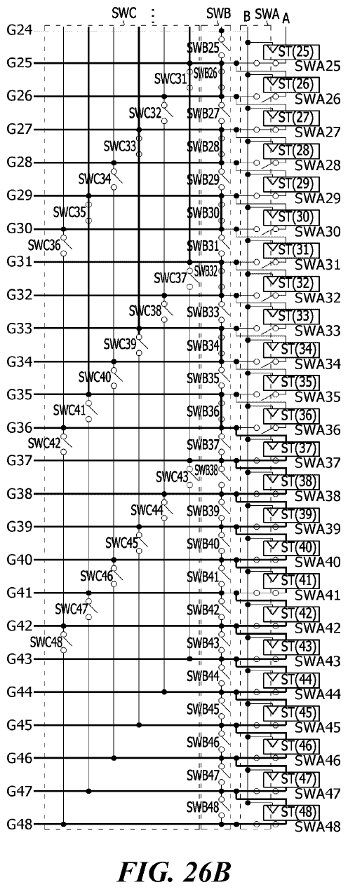

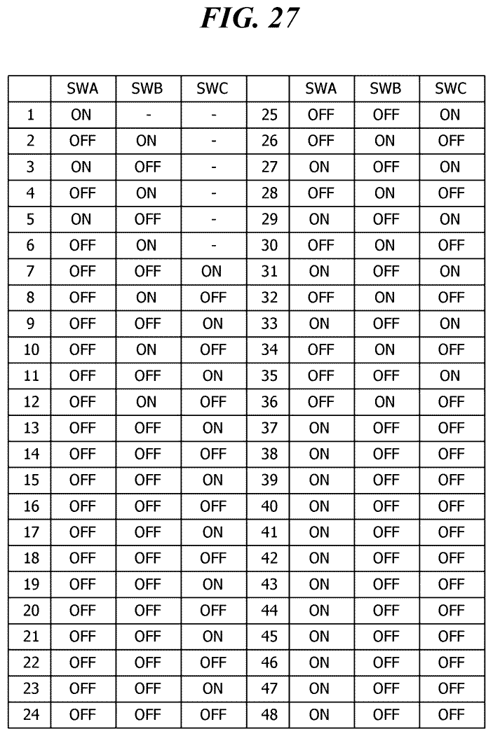

FIGS. 24 to 27 are drawings to explain the operation of a gate driving circuit according to a third embodiment.

Referring to FIG. 24, a screen may be divided into a low-resolution area A1 and a high-resolution area A2 depending on the focus position. In the low-resolution area A1, a plurality of pixels may be driven simultaneously per color in the x-axis and y-axis directions, while in the high resolution area A2, a plurality of pixels may be driven individually.

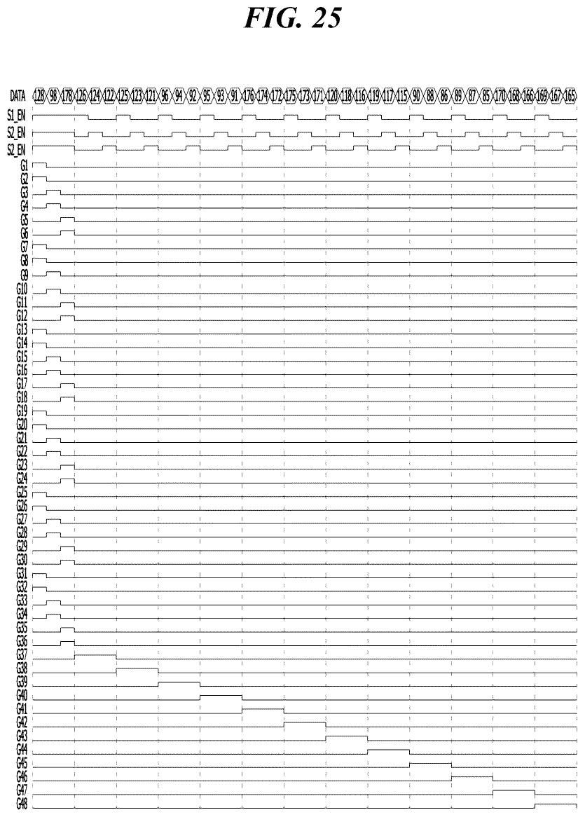

Referring to FIGS. 25 to 27, the gate driving circuit according to an embodiment may keep all switches S1, S2, and S3 of the multiplexer (DeMUX) turned on and may simultaneously drive a plurality of pixels in the low-resolution region A1 in the x-axis and y-axis directions per color. For example, red, green, and blue pixels may be driven sequentially, but each of the red, green, and blue pixels present along the x-axis and y-axis directions may be driven simultaneously.

A first signal transfer unit ST(1) receiving a start signal VST is driven; and a first switch SWA1 in the first switch part SWA, a second switch SWB2, an eighth switch SWB8, a 14th switch SWB14, a 20th switch SWB20, a 26th switch SWB26, a 32nd switch SWB32 in the second switch part SWB, and a seventh switch SWC7, a 13th switch SWC13, a 19th switch SWC19, a 25th switch SWC25, and a 31st switch SWC31 in the third switch part SWC are turned on, allowing the 1st to 2nd, 7th to 8th, 13th to 14th, 19th to 20th, 25th to 26th, and 31st to 32nd gate signals (G1 to G2, G7 to G8, G13 to G14, G19 to G20, G25 to G26, and G31 to G32) to be simultaneously supplied to the gate lines.

Next, a third signal transmission part ST(3), which receives the signal output from the first switch SWA1 in the first switch part SWA as a carry signal, is driven; and a third switch SWA3 in the first switch part SWA and a fourth switch SWB4, a tenth switch SWB10, a 16th switch SWB16, a 24th switch SWB24, a 28th switch SWB28, and a 34th switch SWB34 in the second switch part SWB, and a 9th switch SWC9, a 15th switch SWC15, a 21st switch SWC21, a 27th switch SWC27, and a 33rd switch SWC33 in the third switch part SWC are turned on, allowing the 3rd to 4th, 9th to 10th, 15th to 6th, 21st 22nd, 27th to 28th, and 33rd to 34th gate signals (G3 to G4, G9 to G10, G15 to G16, G21 to G22, G27 to G28, and G33 to G34) to be simultaneously supplied to the gate lines.

Next, a fifth signal transmission part ST(5), which receives the signal output from the third switch SWA3 in the first switch part SWA as a carry signal, is driven; and a fifth switch SWA5 in the first switch part SWA and a sixth switch SWB6, a 12th switch SWB12, an 18th switch SWB18, a 24th switch SWB24, a 30th switch SWB30, a 36th switch SWB36 in the second switch part SWB, and an 11th switch SWC11, a 17th switch SWC17, a 23rd switch SWC23, a 29th switch SWC29, and a 35th switch SWC35 in the third switch part SWC are turned on, allowing 5th to 6th, 11th to 12th, 17th to 18th, 23rd to 24th, 29th to 30th, and 35th to 36th gate signals (G5˜G6, G11˜G12, G17˜G18, G23˜G24, G29˜G30, G35˜G36) to be simultaneously supplied to the gate lines.

The gate driving circuit may sequentially turn on the switches S1, S2, and S3 of the multiplexer (DeMUX) in the high-resolution region A2 and it may individually drive a plurality of pixels for each line.

In the gate driving circuit, in the high-resolution area A2, 37th to 48th signal transmission parts ST(37) to ST(48), which receive the signal output from the fifth switch SWA5 in the first switch part SWA, are driven, and 37th to 48th switches SWA37 to SWA48 are turned on to sequentially supply 37th to 48th gate signals G37 to G48 to the gate lines.

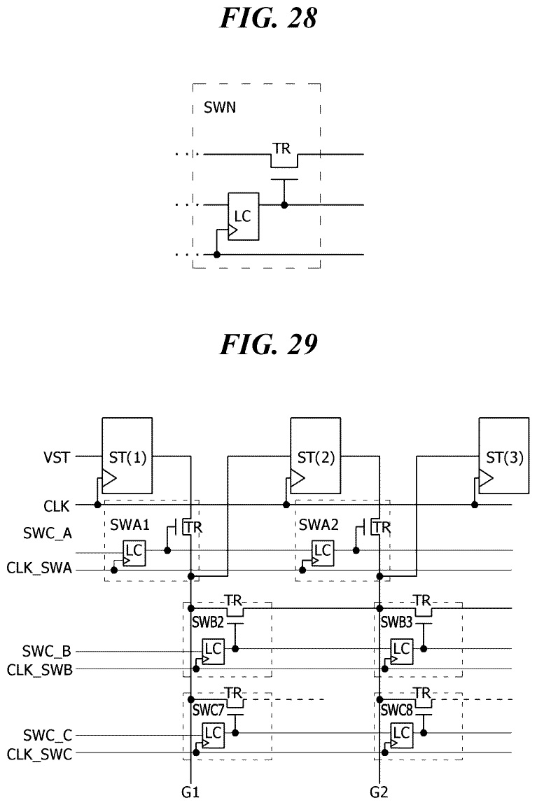

FIGS. 28 to 30 are drawings to explain the operation of a switch according to embodiments.

Referring to FIG. 28, a switch SWN in each of the first switch part SWA (e.g., SWA1, SWA2), the second switch part SWB (e.g., SWB1, SWB2), and the third switch part SWC (e.g., SWC1, SWC2) according to an embodiment may include a logic circuit LC and a transistor TR.

Referring to FIG. 29, the logic circuit LC may be implemented to include a latch, a flip-flop, and the like. The logic circuit LC may receive a setting value for setting the simultaneous operation of switches to store them, and output a switching control signal according to the setting value based on a switch clock signal.

The transistor TR may have a gate electrode connected to the output end of the logic circuit LC and may be turned on/off in response to the switching control signal output from the logic circuit LC. The transistor TR in the first switch part SWA is turned on according to the switching control signal to connect the output end of the signal transmission part and the gate line. The transistor TR in the second switch part SWB is turned on according to the switching control signal to connect the gate line for the pixels that are simultaneously driven in the x-axis direction. The transistor TR in the third switch part SWC is turned on according to the switching control signal to connect the gate line for the pixels that are simultaneously driven in the y-axis direction.

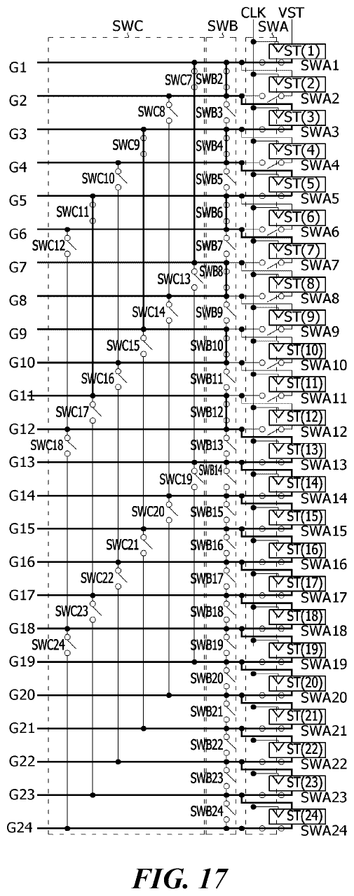

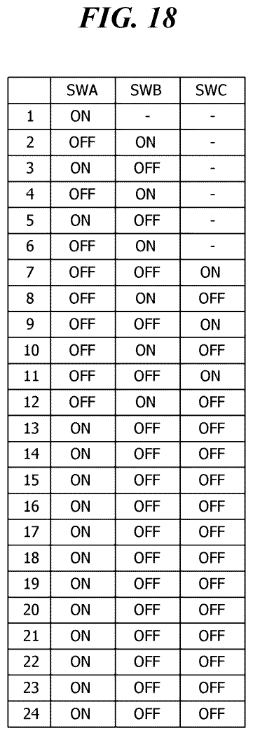

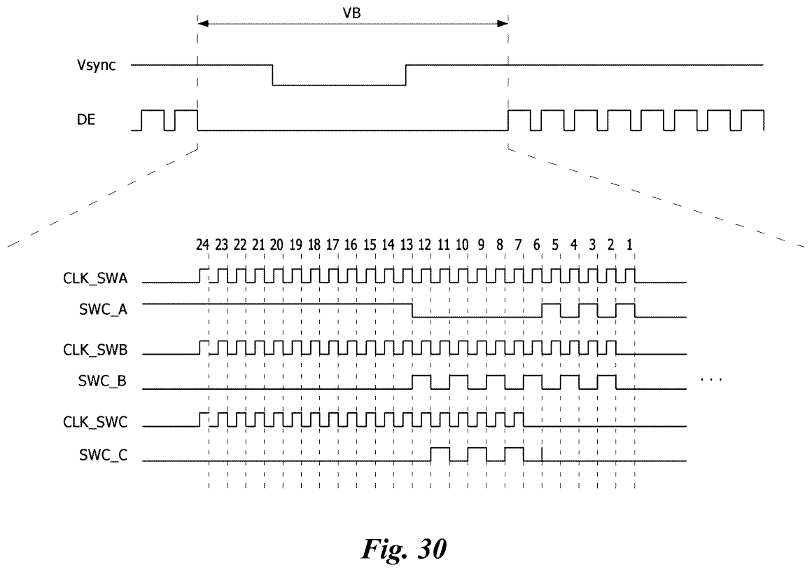

FIG. 30 illustrates setting the state of the switches in a Vertical Black (VB) interval. It show the setting values and the switch clock signals for simultaneous driving of the first switch part SWA, the second switch part SWB, and the third switch part SWC as in FIGS. 17 and 18.

In other words, the switches for simultaneously driving the pixels may be driven according to the setting values based on the switch clock signal. Here, the switch clock signals may serve to turn on the first, third, and fifth switches SWA1, SWA3, and SWA5 in the first switch part SWA, turn on the second, fourth, sixth, eighth, tenth, and twelfth switches SWB2, SWB4, SWB6, SWB8, SWB10, and SWB 12 in the second switch part SWB, and the seventh, ninth, and eleventh switches SWC7, SWC9, and SWC11 in the third switch part SWC.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A gate driving circuit comprising:
a plurality of signal transmission parts connected in cascade by means of a line configured to receive a start signal or a carry signal from a previous signaling unit;
a first switch part connected between an output end of a first signal transmission part of the plurality of signal transmission parts and a first gate line; and
a second switch part connected between the first gate line connected to the first switch part and a second gate line connected to an output end of a second signal transmission part.

2. The gate driving circuit of claim 1, wherein the second switch part is configured to establish a connection to simultaneously drive pixels of a same color in a first-axis direction.

3. The gate driving circuit of claim 1, further comprising:
a third switch part connected between the first gate line connected to the first switch part and a third gate line connected to an output end of a third signal transmission part for a pixel line different from a pixel line of one or more of the first signal transmission part or the second signal transmission part.

4. The gate driving circuit of claim 3, wherein the third switch part is configured to establish a connection to simultaneously drive pixels of a same color in a second-axis direction.

5. The gate driving circuit of claim 3, wherein
each of the first, second, and third switch parts includes:
a logic circuit configured to output a switch control signal according to a pre-stored setting value based on a switch clock signal; and
a transistor configured to be driven by the switch control signal.

6. A display device, comprising:
a pixel array in which data lines and gate lines intersect and a plurality of pixels is arranged in pixel lines;
a data driving circuit configured to apply a data voltage through the data lines; and
a gate driving circuit configured to apply a gate signal through the gate lines,
wherein the gate driving circuit includes:
a plurality of signal transmission parts connected in cascade by means of a line configured to receive a start signal or a carry signal from a previous signaling unit;
a first switch part connected between an output end of a first signal transmission part of the plurality of signal transmission parts and a first gate line; and
a second switch part connected between the first gate line connected to the first switch part and a second gate line connected to an output end of a second transmission part.

7. The display device of claim 6, wherein the second switch part is configured to establish a connection to simultaneously drive pixels of a same color in a first-axis direction.

8. The display device of claim 7, further comprising:
a third switch part configured to establish a connection to simultaneously drive pixels of a same color in a second-axis direction that traverses the first-axis direction.

9. The display device of claim 6, wherein the first gate line and the second gate line correspond to pixels in a same pixel line.

10. The display device of claim 8, wherein the third switch part is connected between gate lines corresponding to pixels in different pixel lines.

11. The display device of claim 6, wherein the plurality of pixels include first, second, and third pixels of different colors that are sequentially disposed in the respective pixel lines.

12. The display device of claim 11, wherein each of the data lines is disposed between two adjacent pixels, and is connected to pixels of a same color for each pixel line.

13. The display device of claim 6, wherein the pixels include first, second, and third pixels of a same color that are disposed in units of pixel lines.

14. The display device of claim 6, wherein the data line is disposed between two adjacent pixels, and is connected to each of the two adjacent pixels.

15. The display device of claim 8, further comprising:
a de-multiplexer disposed between the data driving circuit and the data lines,
wherein the de-multiplexer is configured to connect the data lines to output channels of the data driving circuit simultaneously, or connects the data lines to the output channels sequentially one by one.

16. The display device of claim 8, further comprising:
a controller configured to output signals for controlling the first, the second, and the third switch parts according to a focus position to which the user's gaze is directed or a type of an image.

17. A display device, comprising:
a pixel array including a plurality of pixels;
data lines each coupled to one or more pixels of the plurality of pixels;
gate lines each coupled to one or more pixels of the plurality of pixels; and
a first switch coupled between a first gate line and a second gate line, the first gate line coupled to a first pixel, the second gate line coupled to a second pixel, the first pixel and the second pixel arranged with respect to one another in a first direction.

18. The display device of claim 17, comprising a second switch coupled between the first gate line and a third gate line, the third gate line coupled to a third pixel, the first pixel and the second pixel arranged with respect to one another in a second direction that traverses the first direction.

19. The display device of claim 17, wherein the first pixel and the second pixel are configured to emit light of a same color.

20. The display device of claim 17, wherein among the plurality of pixels, immediately adjacent pixels arranged in the first direction are of a same color, and immediately adjacent pixels arranged in a second direction are of different colors, and the second direction traverses the first direction.
